(19) United States
(12) Patent Application Publication
(10) Pub. No.: US 2013/0098390 A1
(43) Pub. Date: Apr. 25, 2013

(54) DEVICE FOR PROCESSING A CARRIER AND A METHOD FOR PROCESSING A CARRIER

(71) Applicant: Manfred Engelhardt, Villach-Landskron (AT)

(72) Inventor: Manfred Engelhardt, Villach-Landskron (AT)

(73) Assignee: INFINEON TECHNOLOGIES AG, Neubiberg (DE)

(21) Appl. No.: 13/280,482

(22) Filed: Oct. 25, 2011

(51) Int. Cl. B08B 7/00; H01L 21/306

(52) U.S. Cl. 134/1.1; 156/345.43

(57) ABSTRACT

Various embodiments provide a device for processing a carrier, the device including: a carrier receiving portion configured to receive a carrier, the carrier including one or more planar regions and one or more edge regions; a processing portion including: a first electrode; a second electrode, wherein the second electrode is separated from the first electrode; and a dielectric material formed between the first electrode and the second electrode; and wherein the first electrode is configured to receive a first potential and the second electrode is configured to received a second potential to activate supplied gas between the first electrode and the second electrode; wherein the first electrode and the second electrode are arranged to direct more supplied activated gas to the one or more edge regions than to the one or more planar regions of the carrier.

### TECHNICAL FIELD

Various embodiments relate generally a device for processing a carrier, and a method for processing a carrier.

### BACKGROUND

Cleaning of wafer edges, e.g. semiconductor wafer edges, is an important process for removing impurities at wafer edges. In particularly, defect densities should be reduced or removed at wafer edges, e.g. wafer bevel edges, after semiconductor manufacturing processes. Currently, wafer scrubbing, polishing and chemical mechanical polishing are techniques which may be used to polish wafer bevel edges. Unfortunately, defect densities at the wafer bevel edges may not be dissolved using these methods. Plasma cleaning, such as reactive ion etching by exposing wafer bevel edges to plasmas maintained in vacuum chambers, may be carried out. However, the process requires that the process chamber be pumped down to the base pressure prior to the bevel treatment process and vented after the process, thus limiting wafer throughput.

### SUMMARY

Various embodiments provide a device for processing a carrier, the device including: a carrier receiving portion configured to receive a carrier, the carrier including one or more planar regions and one or more edge regions; a processing portion including: a first electrode; a second electrode, wherein the second electrode is separated from the first electrode; and a dielectric material formed between the first electrode and the second electrode; and wherein the first electrode is configured to receive a first potential and the second electrode is configured to received a second potential to activate supplied gas between the first electrode and the second electrode; wherein the first electrode and the second electrode are arranged to direct more supplied activated gas to the one or more edge regions than to the one or more planar regions of the carrier.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a device for processing a carrier according to an embodiment;

FIG. 1B shows a carrier which may be processed by a device according to an embodiment;

FIG. 2 shows a device for processing a carrier according to an embodiment;

FIG. 3A shows a device for processing a carrier according to an embodiment;

FIG. 3B shows a device for processing a carrier according to an embodiment;

FIG. 3C shows a device for processing a carrier according to an embodiment;

FIG. 4 shows a device for processing a carrier according to an embodiment;

FIG. 5 shows a method for processing a carrier according to an embodiment.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over”, used herein to describe forming a feature, e.g. a layer, “over” a side or surface, may be used to mean that the feature, e.g. the layer may be formed “directly on”, e.g. in direct contact with, the implied side or surface. The word “over”, used herein to describe forming a feature, e.g. a layer “over” a side or surface, may be used to mean that the feature, e.g. the layer may be formed “indirectly on” the implied side or surface with one or more additional layers being arranged between the implied side or surface and the formed layer.

Various embodiments relate to using dielectric barrier discharge DBD for the treatment of wafer bevel edges. Wafer bevel edges may be treated by using the principle of generating a dielectric barrier discharge.

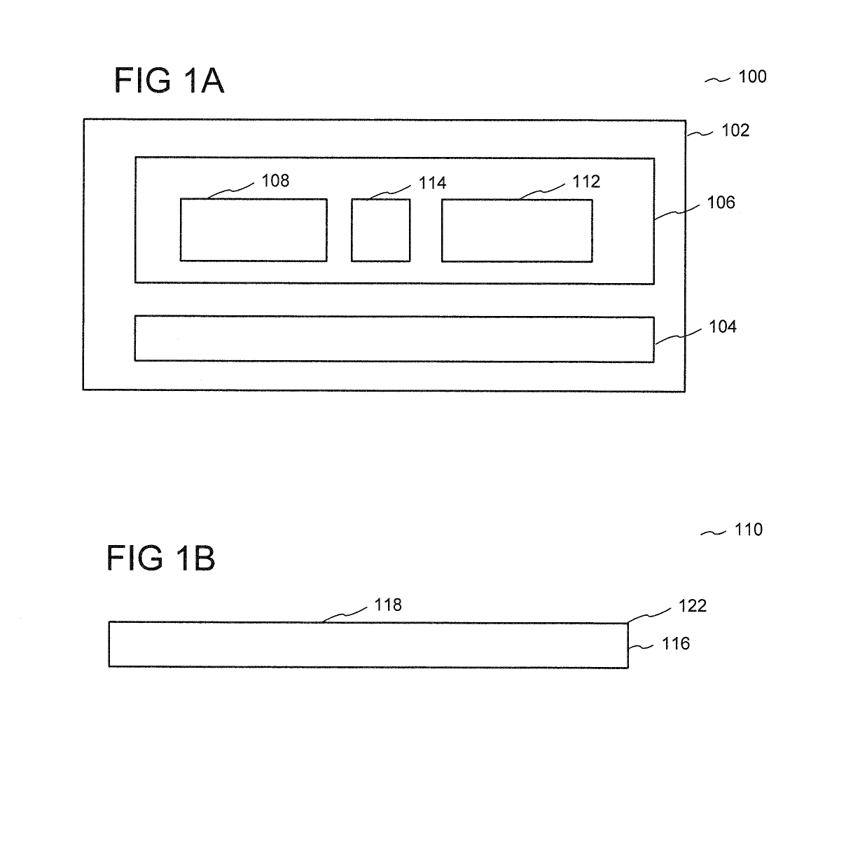

FIG. 1A shows device 102 for processing a carrier 116 (as shown in FIG. 1B) according to an embodiment. Device 102 may include carrier receiving portion 104 configured to receive a carrier 116, the carrier 116 including one or more planar regions 118 and one or more edge regions 122. Device 102 may include processing portion 106 including: first electrode 108; second electrode 112, wherein second electrode 112 may be separated from first electrode 108; and dielectric material 114 formed between first electrode 108 and second electrode 112;

First electrode 108 may be configured to receive a first potential and second electrode 112 may be configured to received a second potential to activate supplied gas between first electrode 108 and second electrode 112; wherein first electrode 108 and second electrode 112 may be arranged to direct more supplied activated gas to the one or more edge regions than to the one or more planar regions of the carrier.

Carrier receiving portion 104 may be configured to receive carrier 116, carrier 116 including a semiconductor wafer including one or more planar regions 118 and one or more edge regions 122. First electrode 108 and second electrode 112 may be arranged to direct more supplied activated gas to one or more edge regions 122 than to one or more planar regions 118 of carrier 116.

Carrier receiving portion 104 may be configured to receive carrier 116, wherein one or more edge regions 122 includes one or more bevel edges of a semiconductor wafer.

Carrier receiving portion 104 may be configured to receive carrier 116, wherein one or more planar regions 118 includes a surface of carrier 116, and wherein one or more edge regions 122 includes one or more edges of the surface of carrier 116.

Carrier receiving portion 104 may be configured to receive carrier 116, wherein one or more edge regions 122 may be positioned directly below or directly above a separation between the first electrode and the second electrode.

Dielectric material 114 may be formed over at least one side of the first electrode. Dielectric material 114 may be formed over at least one side of the second electrode. Dielectric material 114 may include at least one from the following group of materials, the group consisting of quartz, ceramics, SiO₂, SiN, SiON, Al₂O₃, AlN.

Dielectric material 114 may be configured as a dielectric barrier discharge layer, the dielectric barrier discharge layer configured to activate the gas between first electrode 108 and second electrode 112.

Dielectric material 114 may have a thickness ranging from about 1 μm to about 1000 μm.

Carrier receiving portion 104 may be configured to receive carrier 116, wherein one or more edge regions 122 of the carrier define an outer circumference of carrier 116, and wherein one or more planar regions 118 includes one or more portions of a surface of carrier 116 more than about 10 mm from the outer circumference of carrier 116.

Carrier receiving portion 104 may be configured to receive carrier 116, wherein one or more planar regions 118 includes one or more portions of a surface of carrier 116, wherein one or more edge regions 122 of the carrier includes one or more portions of carrier 116, from about 0 mm, to about 10 mm, e.g. about 0 mm, to about 6 mm, e.g. about 0 mm, to about 3 mm, from the outer circumference of carrier 116 into carrier 116, e.g. not more than about 10 mm, e.g. not more than about 6 mm, e.g. not more than about 3 mm from the outer circumference of carrier 116 into carrier 116.

Carrier receiving portion 104 may be configured to receive carrier 116, wherein one or more planar regions 118 of carrier 116 are not arranged between first electrode 108 and second electrode 112.

Supplied gas may include an inert gas.

Supplied gas may include at least one from the following group of elements, the group of elements consisting of: Argon, Helium, Neon, Krypton, Cl2, HCl, NF3, SF6.

First electrode 108 may be configured to receive a first potential and second electrode 112 may be configured to received a second potential wherein the difference between first potential and second potential ranges from about 100 V to about 10000 V. First potential and second potential may include a fixed potential, e.g. a DC potential or an alternating potential, e.g. an AC potential.

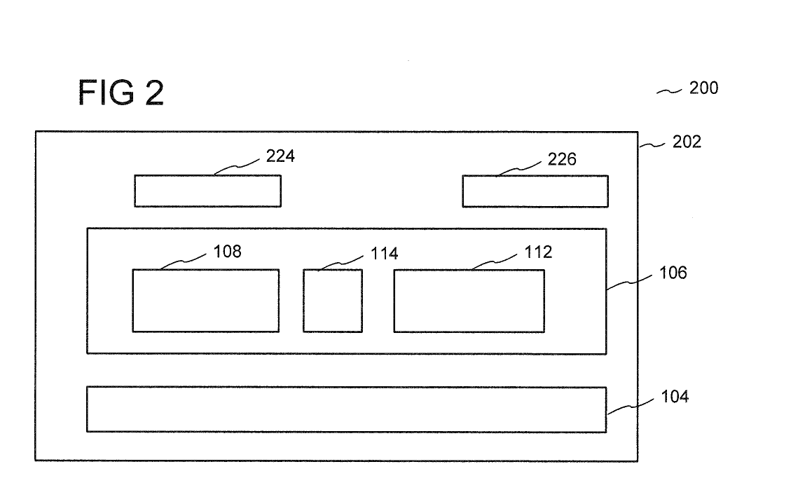

FIG. 2A shows device 202 for processing a carrier according to an embodiment. The basic functionalities of all the features described with respect to device 102 are applicable to device 202, described in further detail below. Like reference numerals already used with respect to device 102 generally refer to the same parts in device 202.

In addition to the features already described above with respect to device 102, device 202 may further include gas supply 224 configured to provide gas for processing a carrier. Device 202 may further include voltage supply 226 configured to supply a first potential to first electrode 208 and a second potential to second electrode 212. Gas supply 224 may be configured to supply gas between first electrode 208 and second electrode 212. Gas supply 224 may be configured to supply gas to the one or more edge regions 122 of the carrier 116.

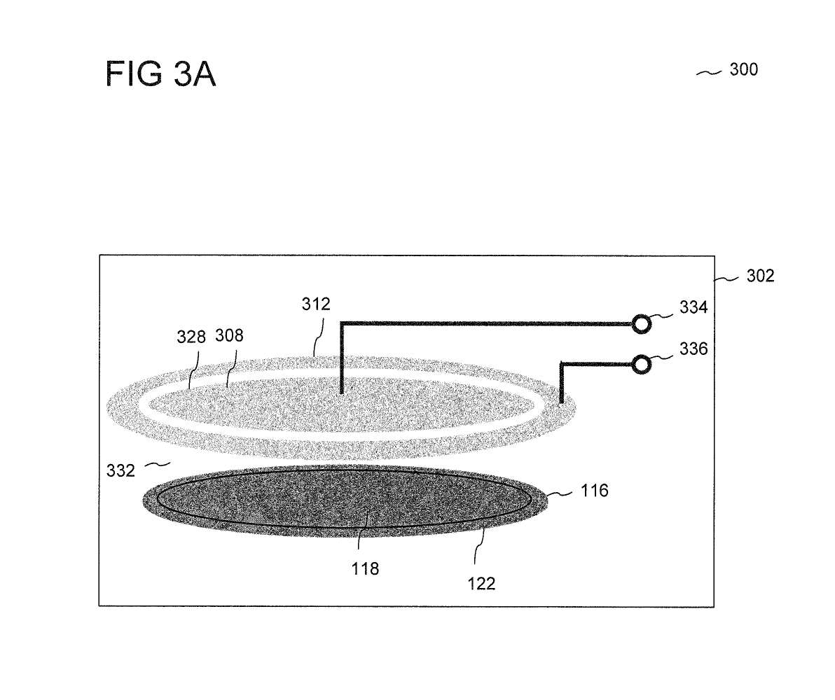

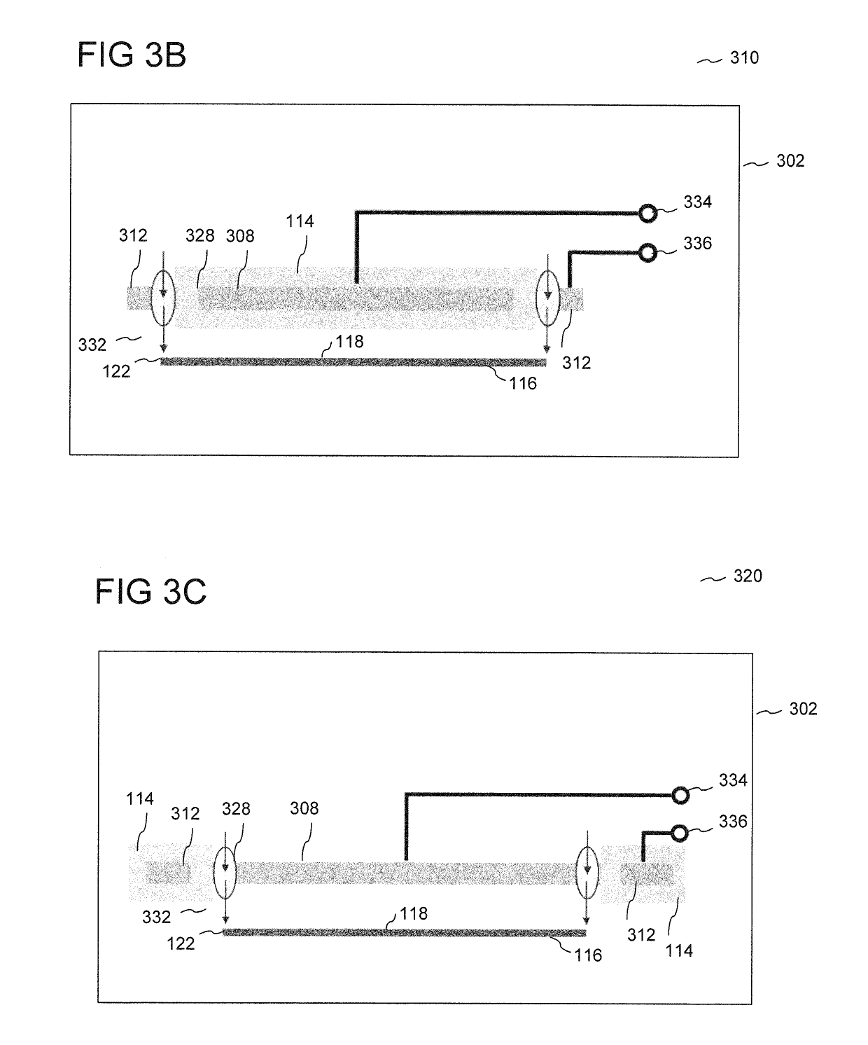

FIG. 3A shows device 302 for processing a carrier according to an embodiment. The basic functionalities of all the features described with respect to device 102 are applicable to device 302, described in further detail below. Like reference numerals already used with respect to device 102 generally refer to the same parts in device 202.

First electrode 308 may include all the basic functionalities of first electrode 108 already described with respect to device 102. Second electrode 312 may include all the basic functionalities of second electrode 112, already described with respect to device 102.

First electrode 308 may further include a first electrode circumference 328; and wherein second electrode 312 may be formed coaxially around first electrode circumference 328. In other words, first electrode 308 may be surrounded in a coaxial way by second electrode 312. First electrode 308 may include a circular shape. Second electrode 312 may have the geometry of a ring, i.e. second 312 may include a ring electrode.

One of first electrode 308 and second electrode 312 may be coated with dielectric material 114. Dielectric material 114 may be configured to form a dielectric barrier discharge i.e. activate the gas, wherein the discharge, i.e. the activated gas will mainly be maintained in the gap between first electrode 308 and second electrode 312 when a potential difference, e.g. a voltage difference, may be applied between first electrode 308 and second electrode 312; i.e, when a first potential 334 is applied to first electrode 308, and second potential 336 is applied to second electrode 312, wherein first potential 334 and second potential 336 may be different.

First electrode 308 may be configured to receive a first potential and second electrode 312 may be configured to received a second potential wherein the difference between first potential and second potential ranges from about 100 V to about 10000 V. First potential and second potential may include a fixed potential, e.g. a DC potential or an alternating potential, e.g. an AC potential.

First electrode 308 may be configured to have a similar geometrical structure, e.g. in terms of shape, e.g. in terms of size, with carrier 116 received by carrier receiving portion 104. Therefore, carrier receiving portion 104 may be configured to receive carrier 116, wherein the first electrode circumference 328 may be substantially aligned with the one or more edge regions 122 of the carrier 116.

Therefore, first electrode 308 may be arranged above carrier 116, e.g. above one or more planar regions 118, such that first electrode circumference 328 may be substantially aligned with the one or more edge regions 122 of the carrier 116. Second electrode 312 may be formed coaxially around first electrode circumference 328, such that the electrode gap between first electrode 308 and second electrode 312 may be substantially aligned with the one or more edge regions 122 of the carrier 116. Carrier receiving portion 104 may be configured to receive carrier 116, wherein the first electrode 308 and the second electrode 312 may be configured on the same side 332 of the carrier 116. For example, both first electrode 308 and the second electrode 312 may be arranged above carrier 116. By arranging first electrode 308 and the second electrode 312 on the same side 332 of the carrier 116, e.g. above one or more planar regions 118 of carrier 116, one or more planar regions 118 may not lie between first electrode 308 and second electrode 312. In other words, one or more planar regions 118 may not lie within a region of activated gas, wherein the region of activate gas lies between between first electrode 308 and second electrode 312 due to supplied gas forming a discharge between first electrode 308 and second electrode 312 when a potential difference is formed between them.

Device 302 may further include gas supply 224 described with respect to device 202. Device 302 may further include voltage supply 226 described with respect to device 202. Process gas may be passed through the electrode gap and will thus be mainly active in the bevel area, e.g. the bevel edge area of carrier 116, i.e the bevel edges of a wafer which in turn may be positioned directly below the electrode gap.

The distance between first electrode 308 and carrier 116 may range from about 0.3 mm to about 20 mm, e.g. about 4 mm to about 15 mm, e.g. about 5 mm, to about 10 mm.

First electrode 308 and second electrode 312 may be separated by a distance ranging from about 0.1 mm to about 3 mm, e.g. a bout 0.15 mm to about 2.5 mm, e.g. about 0.5 mm, to about 1.5 mm.

FIG. 3B shows device 302, as described with respect to FIG. 3A, according to an embodiment, wherein dielectric material 114 may be formed over at least one side of the first electrode 308. Dielectric material 114 may be formed between the first electrode 308 and the second electrode 312. Dielectric material 114 may be further formed over one or more sides of first electrode 308, e.g. dielectric material 114 may be formed over two sides of first electrode 308, e.g. dielectric material 114 may be formed over three sides of first electrode 308, e.g. dielectric material 114 may fully surround first electrode 308 on all sides.

FIG. 3C shows device 302, as described with respect to FIG. 3A, according to an embodiment, wherein dielectric material 114 may be formed over at least one side of the second electrode 312, instead of over at least one side of the first electrode 308. Dielectric material 114 may be further formed over more than one side of second electrode 312, e.g. dielectric material 114 may be formed over two sides of second electrode 312, e.g. dielectric material 114 may be formed over three sides of second electrode 312, e.g. dielectric material 114 may fully surround second electrode 312 on all sides.

As shown in FIGS. 3B and 3C, dielectric material 114 may be formed over either first electrode 308 or second electrode 312, as long as dielectric material is formed between first electrode 308 and second electrode 312. An AC discharge or a DC discharge may be formed when dielectric material is formed over both first electrode 308 and second electrode 312.

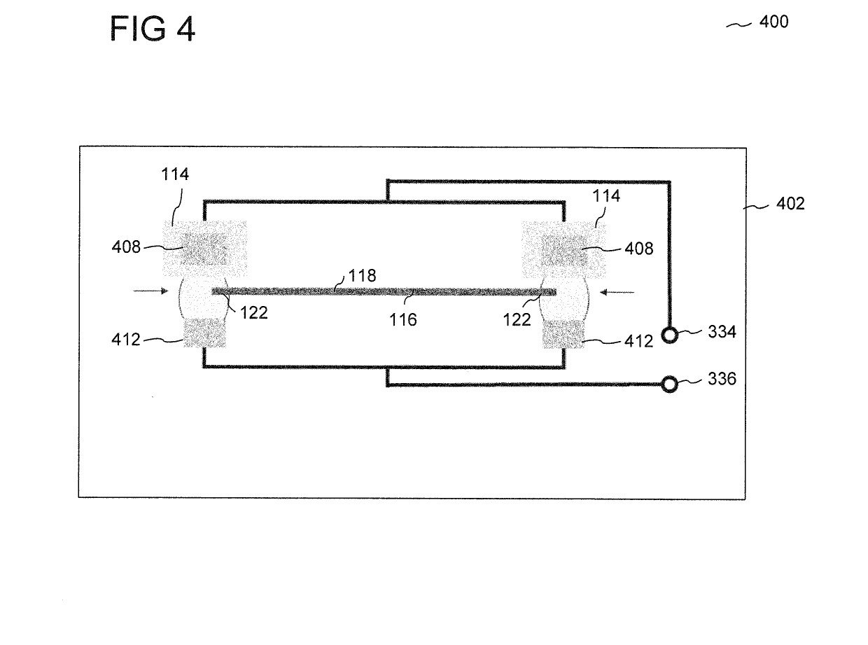

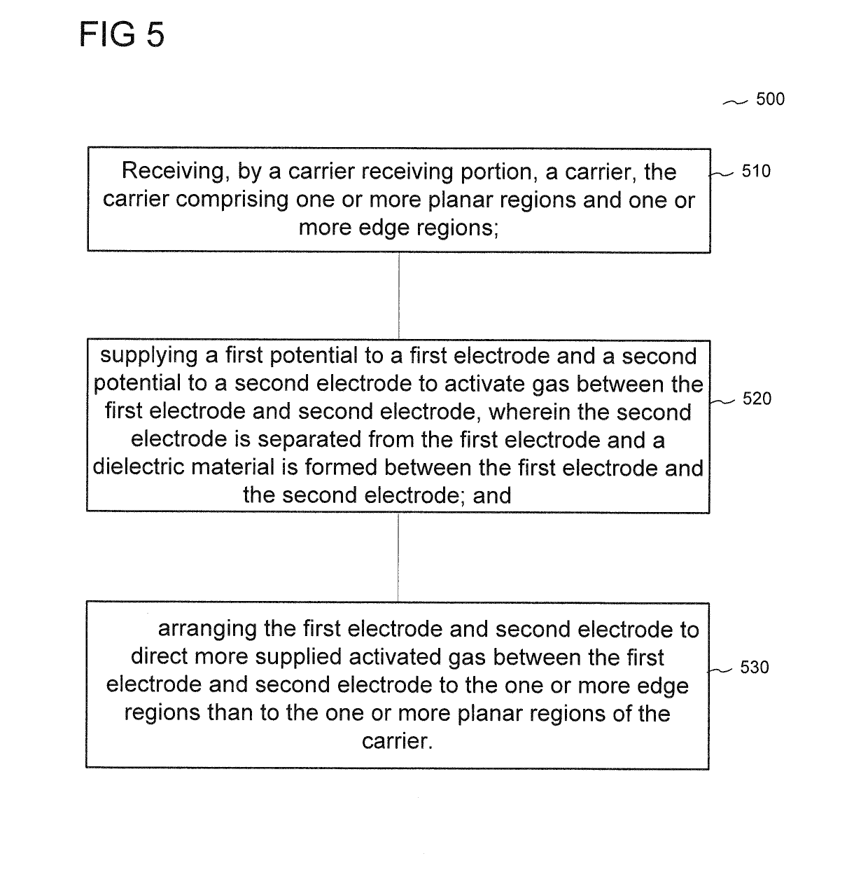

FIG. 4 shows device 402 for processing a carrier according to an embodiment. The basic functionalities of all the features described with respect to device 102 are applicable to device 402, described in further detail below. Like reference numerals already used with respect to device 102 generally refer to the same parts in device 202.

First electrode 408 may include all the basic functionalities of first electrode 108 already described with respect to device 102. Second electrode 412 may include all the basic functionalities of second electrode 112, already described with respect to device 102.

First electrode 408 may include a first ring electrode. Second electrode 412 may include a second ring electrode. Carrier receiving portion 104 may be configured to receive carrier 116, wherein the carrier 116 may be arranged between the first ring electrode 408 and the second ring electrode 412.

Carrier receiving portion 104 may be configured to receive carrier 116, wherein the one or more edge regions 122 of the carrier 116 may be arranged between the first ring electrode 408 and the second electrode 412.

Carrier receiving portion 104 may be configured to receive carrier 116, wherein the one or more edge regions 122 of the carrier 116 may be positioned directly between the first electrode 408 and second electrode 412.

Carrier receiving portion 104 may be configured to receive carrier 116, wherein the one or more edge regions 122 of the carrier 116 may be positioned directly within regions of activated gas, the activated gas being between the first electrode 408 and second electrode 412.

By arranging first electrode 308 and the second electrode 312 on the same side 332 of the carrier 116, e.g. above one or more planar regions 118 of carrier 116, one or more planar regions 118 may not lie between first electrode 308 and second electrode 312. In other words, one or more planar regions 118 may not lie within a region of activated gas, wherein the region of activate gas lies between between first electrode 308 and second electrode 312 due to supplied gas forming a discharge between first electrode 308 and second electrode 312 when a potential difference is formed between them.

As first electrode 408 and second electrode 412 may be configured as ring electrodes, activated gas may be mainly formed in a ring shape corresponding to the spaces between first electrode 408 and second electrode 412. In other words, one or more edge regions of the carrier 122 may be arranged to lie within the activated gas region formed in a ring shape corresponding to the spaces between first electrode 408 and second electrode 412. One or more planar regions 118 may not lie within the region of activated gas formed in a ring shape corresponding to the spaces between first electrode 408 and second electrode 412. Therefore, more activated gas may be supplied to the one or more edge regions 122 than to the one or more planar regions of the carrier 118.

Dielectric material 114 may be formed over at least one side of one of first electrode 308 or second electrode 312. Dielectric material 114 may be further formed over more than one side of one of first electrode 308 or second electrode 312, e.g. dielectric material 114 may be formed over two sides of one of first electrode 308 or second electrode 312, e.g. dielectric material 114 may be formed over three sides of one of first electrode 308 or second electrode 312, e.g. dielectric material 114 may fully surround one of first electrode 308 or second electrode 312 on all sides.

Device 402 may further include gas supply 224 described with respect to device 202. Device 402 may further include voltage supply 226 described with respect to device 202.

FIG. 5 shows method 500 for processing a carrier according to an embodiment. The method includes: receiving, by a carrier receiving portion, a carrier, the carrier including one or more planar regions and one or more edge regions (in 510); supplying a first potential to a first electrode and a second potential to a second electrode to activate gas between the first electrode and second electrode, wherein the second electrode is separated from the first electrode and a dielectric material is formed between the first electrode and the second electrode (in 520); and arranging the first electrode and second electrode to direct more supplied activated gas between the first electrode and second electrode to the one or more edge regions than to the one or more planar regions of the carrier (in 530).

Various embodiments provide a device for processing a carrier, the device including: a carrier receiving portion configured to receive a carrier, the carrier including one or more planar regions and one or more edge regions; a processing portion including: a first electrode; a second electrode, wherein the second electrode is separated from the first electrode; and a dielectric material formed between the first electrode and the second electrode; and wherein the first electrode is configured to receive a first potential and the second electrode is configured to received a second potential to activate supplied gas between the first electrode and the second electrode; wherein the first electrode and the second electrode are arranged to direct more supplied activated gas to the one or more edge regions than to the one or more planar regions of the carrier.

According to various embodiments, the device further includes a gas supply configured to provide gas for processing a carrier.

According to various embodiments, the device further includes a voltage supply configured to supply a first potential to the first electrode and a second potential to the second electrode.

According to various embodiments, the carrier receiving portion is configured to receive a carrier, the carrier including a semiconductor wafer including the one or more planar regions and the one or more edge regions.

According to various embodiments, the carrier receiving portion is configured to receive a carrier, wherein the one or more edge regions includes one or more bevel edges of a semiconductor wafer.

According to various embodiments, the carrier receiving portion is configured to receive a carrier, wherein the one or more planar regions includes a surface of the carrier, and wherein the one or more edge regions includes one or more edges of the surface of the carrier.

According to various embodiments, the carrier receiving portion is configured to receive a carrier, wherein the one or more edge regions of the carrier define an outer circumference of the carrier, and wherein the one or more planar regions includes one or more portions of a surface of the carrier more than about 10 mm from the outer circumference of the carrier.

According to various embodiments, the carrier receiving portion is configured to receive a carrier, wherein the one or more edge regions are positioned directly below or directly above a separation between the first electrode and the second electrode.

According to various embodiments, the carrier receiving portion is configured to receive a carrier, wherein the first electrode and the second electrode are configured on the same side of the carrier.

According to various embodiments, the carrier receiving portion is configured to receive a carrier, wherein the one or more edge regions of the carrier are positioned directly between the first electrode and second electrode.

According to various embodiments, the carrier receiving portion is configured to receive a carrier, wherein the one or more planar regions of the carrier are not between the first electrode and second electrode.

According to various embodiments, the dielectric material is formed over at least one side of the first electrode.

According to various embodiments, the dielectric material is formed over at least one side of the second electrode.

According to various embodiments, the dielectric material includes at least one from the following group of materials, the group consisting of quartz, ceramics, SiO₂, SiN, SiON, Al₂O₃, AlN.

According to various embodiments, the dielectric material is configured as a dielectric barrier discharge layer, the dielectric barrier discharge layer configured to activate the gas between the first electrode and the second electrode.

According to various embodiments, the first electrode includes a first electrode circumference; and wherein the second electrode is formed coaxially around the first electrode circumference.

According to various embodiments, the carrier receiving portion is configured to receive the carrier, wherein the first electrode circumference is substantially aligned with the one or more edge regions of the carrier.

According to various embodiments, the first electrode includes a first ring electrode; wherein the second electrode includes a second ring electrode; and wherein the carrier receiving portion is configured to receive the carrier, wherein the carrier is arranged between the first ring electrode and the second ring electrode.

According to various embodiments, the carrier receiving portion is configured to receive the carrier, wherein the one or more edge regions of the carrier are arranged between the first ring electrode and the second electrode.

According to various embodiments, the gas supply may be configured to supply gas between the first electrode and the second electrode.

According to various embodiments, the gas supply may be configured to supply gas to the one or more edge regions of the carrier.

According to various embodiments, the supplied gas includes at least one from the following group of elements, the group of elements consisting of: Argon, Helium, Neon, Krypton, Cl₂, HCl, NF₃, SF₆.

Various embodiments provide a method for processing a carrier, the method including receiving, by a carrier receiving portion, a carrier, the carrier including one or more planar regions and one or more edge regions; supplying a first potential to a first electrode and a second potential to a second electrode to activate gas between the first electrode and second electrode, wherein the second electrode is separated from the first electrode and a dielectric material is formed between the first electrode and the second electrode; and arranging the first electrode and second electrode to direct more supplied activated gas between the first electrode and second electrode to the one or more edge regions than to the one or more planar regions of the carrier.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A device for processing a carrier, the device comprising:
a carrier receiving portion configured to receive a carrier, the carrier comprising one or more planar regions and one or more edge regions;
a processing portion comprising:
a first electrode;
a second electrode, wherein the second electrode is separated from the first electrode; and
a dielectric material formed between the first electrode and the second electrode; and
wherein the first electrode is configured to receive a first potential and the second electrode is configured to received a second potential to activate supplied gas between the first electrode and the second electrode;
wherein the first electrode and the second electrode are arranged to direct more supplied activated gas to the one or more edge regions than to the one or more planar regions of the carrier.

2. The device according to claim 1, further comprising
a gas supply configured to provide gas for processing a carrier.

3. The device according to claim 1, further comprising
a voltage supply configured to supply a first potential to the first electrode and a second potential to the second electrode.

4. The device according to claim 1, wherein
the carrier receiving portion is configured to receive a carrier,
the carrier comprising a semiconductor wafer comprising the one or more planar regions and the one or more edge regions.

5. The device according to claim 1, wherein
the carrier receiving portion is configured to receive a carrier,
wherein the one or more edge regions comprises one or more bevel edges of a semiconductor wafer.

6. The device according to claim 1, wherein
the carrier receiving portion is configured to receive a carrier,
wherein the one or more planar regions comprises a surface of the carrier, and
wherein the one or more edge regions comprises one or more edges of the surface of the carrier.

7. The device according to claim 1, wherein
the carrier receiving portion is configured to receive a carrier,
wherein the one or more edge regions of the carrier define an outer circumference of the carrier, and
wherein the one or more planar regions comprises one or more portions of a surface of the carrier more than about 10 mm from the outer circumference of the carrier.

8. The device according to claim 1, wherein
the carrier receiving portion is configured to receive a carrier,
wherein the one or more edge regions are positioned directly below or directly above a separation between the first electrode and the second electrode.

9. The device according to claim 1, wherein
the carrier receiving portion is configured to receive a carrier,
wherein the first electrode and the second electrode are configured on the same side of the carrier.

10. The device according to claim 1, wherein
the carrier receiving portion is configured to receive a carrier,
wherein the one or more edge regions of the carrier are positioned directly between the first electrode and second electrode.

11. The device according to claim 1, wherein
the carrier receiving portion is configured to receive a carrier, wherein the one or more planar regions of the carrier are not between the first electrode and second electrode.

12. The device according to claim 1, wherein
the dielectric material is formed over at least one side of the first electrode.

13. The device according to claim 1, wherein
the dielectric material is formed over at least one side of the second electrode.

14. The device according to claim 1, wherein
the dielectric material comprises at least one from the following group of materials, the group consisting of: quartz, ceramics, SiO₂, SiN, SiON, Al₂O₃, AlN

15. The device according to claim 1, wherein
the dielectric material is configured as a dielectric barrier discharge layer, the dielectric barrier discharge layer configured to activate the gas between the first electrode and the second electrode.

16. The device according to claim 1, wherein
the first electrode comprises a first electrode circumference; and
wherein the second electrode is formed coaxially around the first electrode circumference.

17. The device according to claim 16, wherein
the carrier receiving portion is configured to receive the carrier, wherein
the first electrode circumference is substantially aligned with the one or more edge regions of the carrier.

18. The device according to claim 1, wherein
the first electrode comprises a first ring electrode;
wherein the second electrode comprises a second ring electrode;
and wherein the carrier receiving portion is configured to receive the carrier,
wherein the carrier is arranged between the first ring electrode and the second ring electrode.

19. The device according to claim 18, wherein
the carrier receiving portion is configured to receive the carrier,
wherein the one or more edge regions of the carrier are arranged between the first ring electrode and the second electrode.

20. The device according to claim 1, wherein
the gas supply may be configured to supply gas between the first electrode and the second electrode.

21. The device according to claim 2, wherein
the gas supply may be configured to supply gas to the one or more edge regions of the carrier.

22. The device according to claim 1, wherein
wherein the supplied gas comprises at least one from the following group of elements, the group of elements consisting of: Argon, Helium, Neon, Krypton, Cl₂, HCl, NF₃, SF₆.

23. A method for processing a carrier, the method comprising:
receiving, by a carrier receiving portion, a carrier, the carrier comprising one or more planar regions and one or more edge regions;
supplying a first potential to a first electrode and a second potential to a second electrode to activate gas between the first electrode and second electrode, wherein the second electrode is separated from the first electrode and a dielectric material is formed between the first electrode and the second electrode; and
arranging the first electrode and second electrode to direct more supplied activated gas between the first electrode and second electrode to the one or more edge regions than to the one or more planar regions of the carrier.
